(19) United States
(12) Patent Application Publication
(10) Pub. No.: US 2023/0420530 A1
(43) Pub. Date: Dec. 28, 2023

(54) FORMING A FORKSHEET NANODEVICE

(71) Applicant: International Business Machines Corporation, Armonk, NY (US)

(72) Inventors: Ruilong Xie, Niskayuna, NY (US); REINALDO VEGA, Mahopac, NY (US); Julien Frougier, Albany, NY (US); Kangguo Cheng, Schenectady, NY (US)

(21) Appl. No.: 17/849,639

(22) Filed: Jun. 25, 2022

(51) Int. Cl. H01L 29/423; H01L 29/786; H01L 29/66; H01L 29/06

(52) U.S. Cl. CPC H01L 29/42392; H01L 29/78696; H01L 29/66439; H01L 29/0665

(57) ABSTRACT

A semiconductor structure includes a common substrate; a first forksheet complementary metal oxide semiconductor (CMOS) device that is located on the common substrate and that has an nFET (n-doped Field Effect Transistor) and a pFET (p-doped Field Effect Transistor) and has a first β (effective width ratio) between the nFET and the pFET; and a second forksheet device that is adjacent to the first forksheet device on the common substrate and that has a second β between a second nFET and a second pFET. The second β is different than the first β by at least 5 percent. Another semiconductor structure includes a common substrate; a forksheet complementary metal oxide semiconductor (CMOS) device that is located on the common substrate; and a gate-all-around (GAA) nanosheet CMOS device that is located on the common substrate and is adjacent to the forksheet device.

### BACKGROUND

The present invention relates to the electrical, electronic, and computer arts, and more specifically, to semiconductor device fabrication.

Forksheet transistors are a type of semiconductor device that can be formed by etching layered nanosheets to form left and right portions of the etched nanosheets, then depositing a dielectric pillar between the left and right portions. Forksheets are expected to support 2 nm production nodes for field effect transistors (FETs).

The lithographic etching process currently used in forming forksheets can be misaligned so that β (an effective width (Weff) ratio) of the left- and right-hand portions diverges from an expected value (often 1:1). Misalignment can be averted by growing spacers on the sides of hardmask columns, before etching; however, the spacer-formation-and-cut approach limits β to 1:1, which may not always be desired.

### SUMMARY

Principles of the invention provide techniques for forming a forksheet nanodevice.

In one aspect, an exemplary semiconductor structure includes a common substrate; a forksheet CMOS device located on the common substrate; and a gate-all-around nanosheet CMOS device, located on the common substrate, which is adjacent to the forksheet device.

In another aspect, an exemplary method includes etching a hardmask on a nanosheet stack to simultaneously form a plurality of hardmask caps over a plurality of pFET (p-doped Field Effect Transistor) and nFET (n-doped Field Effect Transistor) precursor regions, wherein spaces of varying widths separate the hardmask caps at different locations of the nanosheet stack; depositing spacers on the hardmask and reactive ion etching the spacers to form gaps that correspond to the spaces that were separating the hardmask caps; forming trenches of varying widths by etching the nanosheet stack through the gaps; depositing a sacrificial liner with a liner thickness on the hardmask caps and into the trenches; isotropically etching back the sacrificial liner so that portions of the sacrificial liner are removed from trenches that are wider than twice the liner thickness, while other portions of the sacrificial liner remain in pinch-off trenches that are narrower than twice the liner thickness; and completing a plurality of complementary metal-oxide-silicon transistors that include p-doped and n-doped source/drain structures in respective ones of the pFET and the nFET precursor regions, wherein dielectric material fills the trenches between the pFET and nFET precursor regions.

According to another aspect, an exemplary semiconductor structure includes a common substrate; a first forksheet device that is located on the common substrate and that has an nFET (n-doped Field Effect Transistor) and a pFET (p-doped Field Effect Transistor) and has a first β (effective width ratio) between the nFET and the pFET; and a second forksheet device that is adjacent to the first forksheet device on the common substrate and that has a second β between a second nFET and a second pFET, wherein the second β is different than the first β by at least 5 percent.

In view of the foregoing, techniques of the present invention can provide substantial beneficial technical effects. For example, one or more embodiments provide one or more of:

Forming a forksheet nanodevice with arbitrary β between left and right (pFET and nFET) portions of the device.

Forming an array of forksheet nanodevices with well-controlled spacing of transistors.

Forming an array of CMOS transistors that includes both forksheet nanodevices and gate-all-around nanodevices adjacent to each other.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1A depicts a first side view of a forksheet nanodevice, according to exemplary embodiments.

FIGS. 1B, 1C, and 1D depict additional side views of the forksheet nanodevice, perpendicular to FIG. 1A, according to exemplary embodiments.

FIG. 1E depicts a top view of the forksheet nanodevice, as shown in FIGS. 1A-1D, according to exemplary embodiments.

FIG. 2 depicts in a flow chart a method for forming the forksheet nanodevice that is shown in FIGS. 1A-1E, according to exemplary embodiments.

FIGS. 3A-3D depict side views of a precursor to the forksheet nanodevice, as shown in FIGS. 1A-1E, according to exemplary embodiments.

FIGS. 4A-4D depict side views of a precursor to the forksheet nanodevice, as shown in FIGS. 1A-1E, according to exemplary embodiments.

FIGS. 5A-5D depict side views of a precursor to the forksheet nanodevice, as shown in FIGS. 1A-1E, according to exemplary embodiments.

FIGS. 6A-6D depict side views of a precursor to the forksheet nanodevice, as shown in FIGS. 1A-1E, according to exemplary embodiments.

FIGS. 7A-7D depict side views of a precursor to the forksheet nanodevice, as shown in FIGS. 1A-1E, according to exemplary embodiments.

FIGS. 8A-8D depict side views of a precursor to the forksheet nanodevice, as shown in FIGS. 1A-1E, according to exemplary embodiments.

FIGS. 9A-9D depict side views of a precursor to the forksheet nanodevice, as shown in FIGS. 1A-1E, according to exemplary embodiments.

FIGS. 10A-10D depict side views of a precursor to the forksheet nanodevice, as shown in FIGS. 1A-1E, according to exemplary embodiments.

### DETAILED DESCRIPTION

The ordinary skilled worker will appreciate that it is desirable to be able to provide semiconductor devices, such as complementary metal oxide semiconductor (CMOS) transistors, at an arbitrarily small scale (e.g., on the order of 10 nm process node or smaller) with an arbitrary ratio of effective width between the nFET and pFET portions of the CMOS.

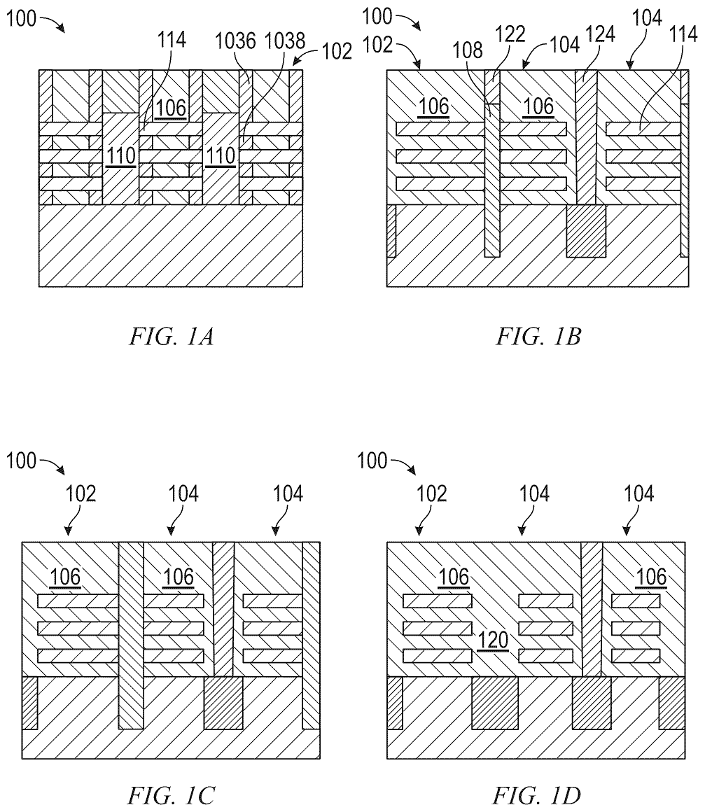

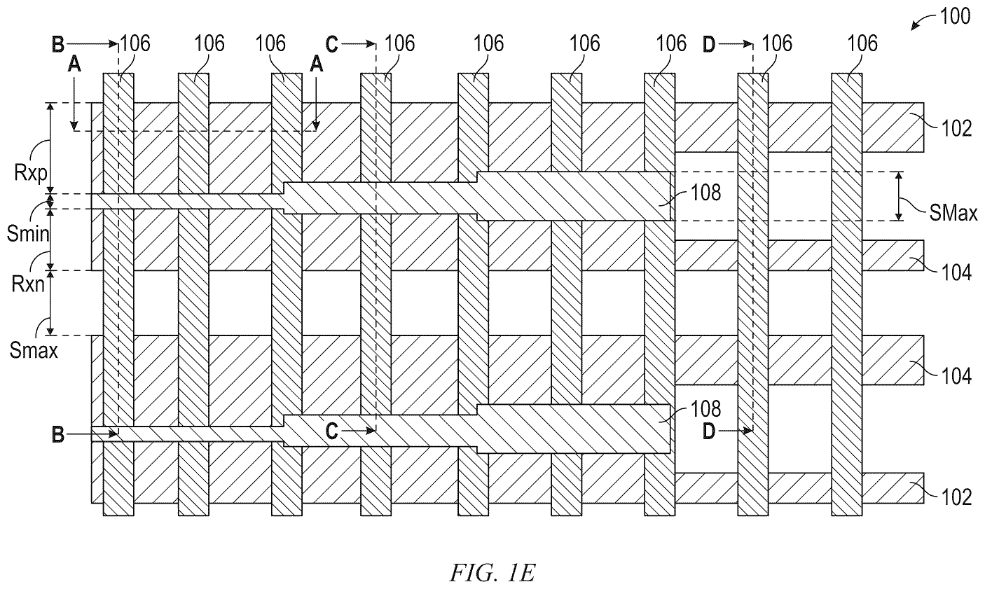

FIG. 1A depicts a side view of a semiconductor structure 100 (including a plurality of CMOS devices), which includes a pFET 102. The pFET 102 includes gate stacks 106, p-doped source/drain structures 110, semiconductor (e.g., silicon or silicon-germanium) nanosheets 114, and dielectric spacers 1036 and 1038. Referring to FIGS. 1B, 1C, and 1D, which depict side views of the semiconductor structure 100 that are perpendicular to FIG. 1A along the corresponding B, C, and D cut lines shown in FIG. 1E, the semiconductor structure 100 also includes nFETs 104, which include gate stacks 106 as well as more of the nanosheets 114. The semiconductor structure 100 also includes dielectric pillars 108 that separate the nFET gate stacks from the pFET gate stacks, central gate metal pillars 120 that connect the nFET gate stacks to the pFET gate stacks, metallic shared gate connectors 122 that bridge the gate stacks across the dielectric pillar 108 for certain nFETs and pFETs, and gate cut dielectric pillars 124 that separate adjacent nFETs or pFETs.

FIG. 1E depicts a top view of the semiconductor structure 100. Components shown in FIG. 1E already have been discussed with reference to FIGS. 1A-1D. Generally, active region widths Rxₚ of the pFETs 102 vary along a length of the structure 100 (left to right), with the pFETs being wider at the left side. Active region widths Rxₙ of the nFETs 104 also vary from wider at the left side to narrower at the right side. “Left” and “right,” in this context, are used as arbitrary terms; indeed, the FETs may be wider at the middle or at the “right” end of the structure, without departing from the intent of the invention. It also should be understood that the top view FIG. 1E is a partial view, and that the structure may continue in any direction across the figure and in one or more layers above or below the figure. Generally, when combined active region size Rxₚ+Rxₙ is wide, such that the N2P space (between nFET and pFET of a same CMOS device) is small (ranging from Smin to Smax), the N2P space will be filled with dielectric 108 and an nFET/pFET device attached to the dielectric 108 becomes a forksheet device (as shown in FIG. 1B, and in FIG. 1C along lines B and C). On the other hand, when the combined active region size Rxₚ+Rxₙ is small, such that the N2P space is wider than Smax, no dielectric pillar will be formed, and the devices are gate-all-around nanosheet devices (as shown in FIG. 1D along line D). Views of FIGS. 1A-1D are taken along the cut-lines shown in FIG. 1E.

In FIGS. 1A-1E, a gate stack 106 represents collectively a gate dielectric, work function material (WFM), and conductive gate metal for each field effect transistor (FET) in the complementary metal-oxide-semiconductor (CMOS) structure, where the WFM for n-type FET (nFET) is different (lower work function) than the WFM for p-type FET (pFET), as will be appreciated by the skilled worker.

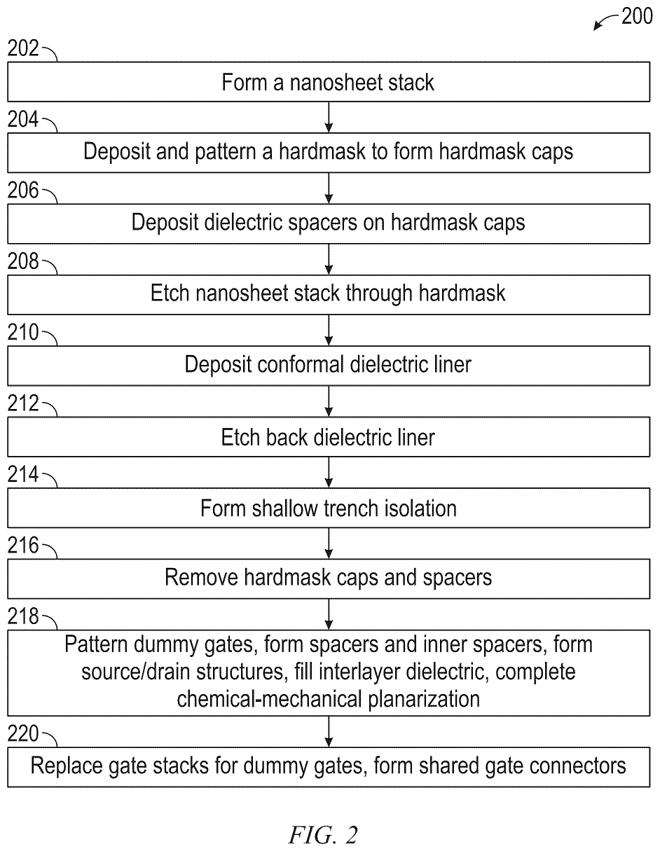

Notably, a P/N ratio of effective widths (β) is equal to Rxₚ/Rxₚ. β varies along the semiconductor structure 100 in a manner that has not been achieved by prior art methods. This is accomplished according to a method 200, which is further described with reference to FIG. 2.

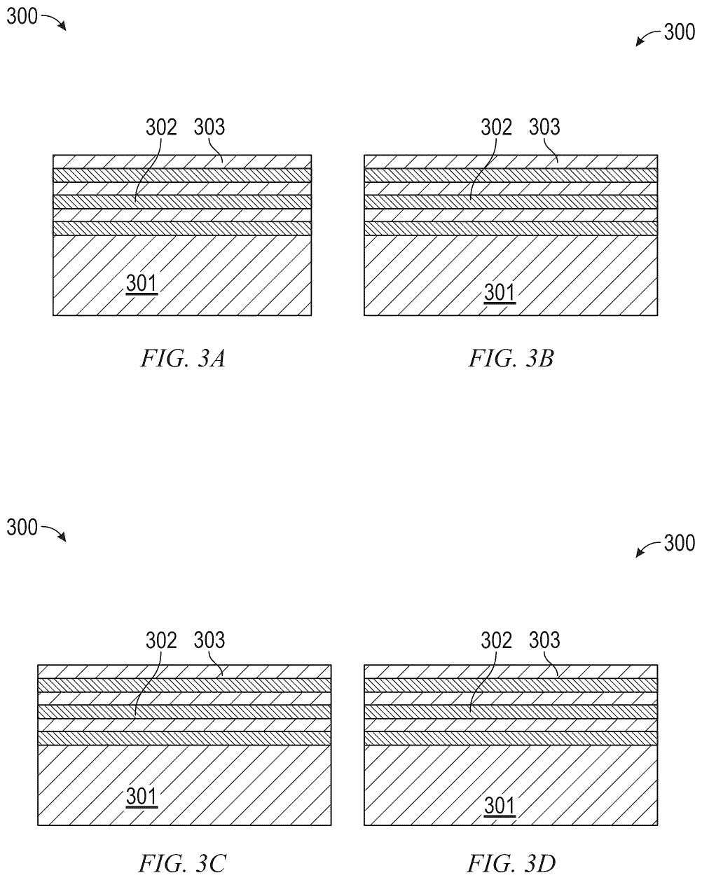

FIG. 2 depicts a flow chart of the method 200 for fabricating the semiconductor structure 100. At 202, form an initial nanosheet stack 300 as shown in FIGS. 3A-3D. The nanosheet stack 300 includes a first semiconductor (e.g., silicon) substrate 301 as well as a plurality of second semiconductor (e.g., silicon-germanium) nanosheets 302 and another plurality of third semiconductor (e.g., silicon) nanosheets 303.

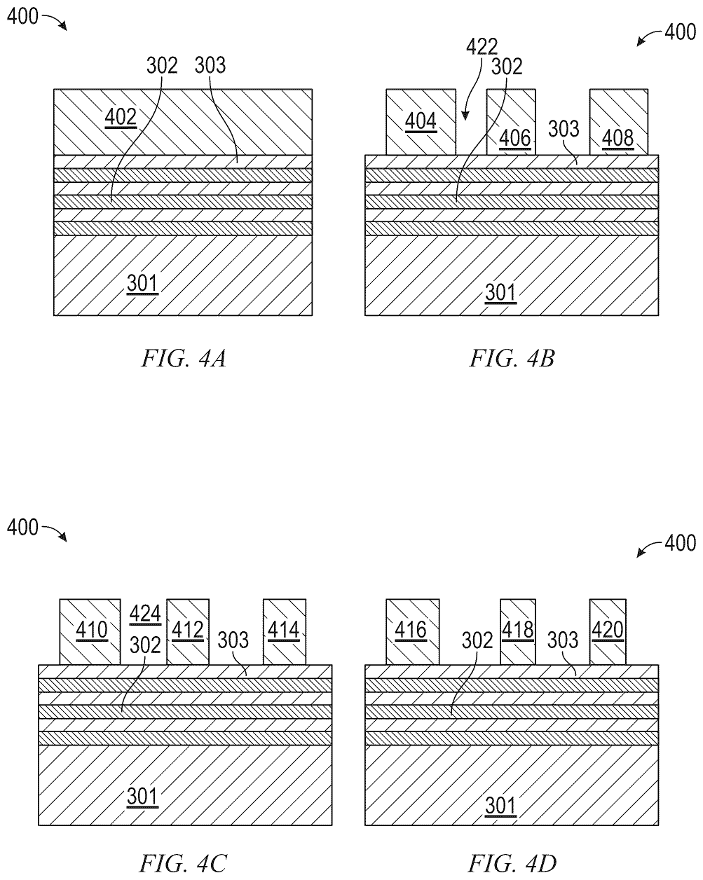

At 204, deposit and pattern a hardmask 402 to form a structure 400, as shown in FIGS. 4A-4D. The patterning of the hardmask 402 forms pFET and nFET hardmask caps 404, 406, 408, 410, 412, 414, 416, 418, 420 that have varying widths and spacings, e.g., pFET cap 404 is wider than is pFET cap 410, which in turn is wider than is pFET cap 416. Similarly, nFET cap 406 is of a different width than is nFET cap 408. Moreover, a gap 422 between pFET cap 404 and nFET cap 406 is of a different with than is a gap 424 between pFET cap 410 and nFET cap 412. Generally, the hardmask patterning with variable size and space of step 204, as shown in FIGS. 4A-4D, sets up the varying widths that are shown in FIG. 1E. Thus, FIGS. 4A-4D depict an aspect of the invention.

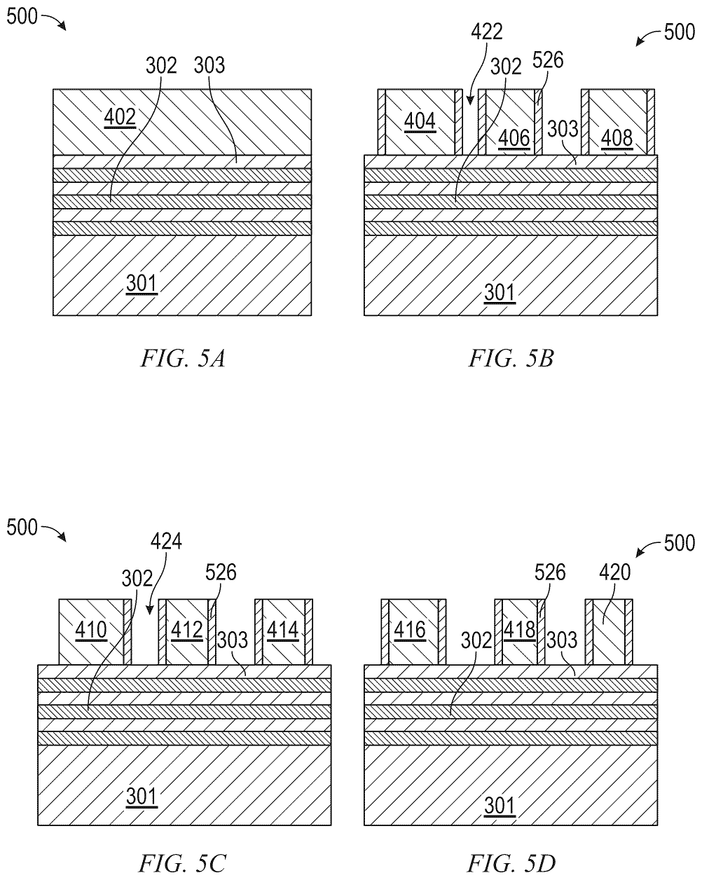

At 206, form a structure 500 by depositing dielectric spacers 526 on the various hardmask caps, as shown in FIGS. 5A-5D. The dielectric spacers 526 are of uniform thickness; they narrow the gaps between the hardmask caps. This sets up a later step of forming dielectric pillars that will be thinner than could be achieved by lithography and etch process only. In one or more embodiments, the dielectric spacers 526 define N2P (nFET-to-pFET) gaps that are on the order of 8 nm wide. Note that “N2N” refers to spaces between adjacent n-type FETs (nFETs); “P2P” refers to spaces between adjacent p-type FETs (pFETs); and “N2P” refers to spaces between adjacent nFETs and pFETs.

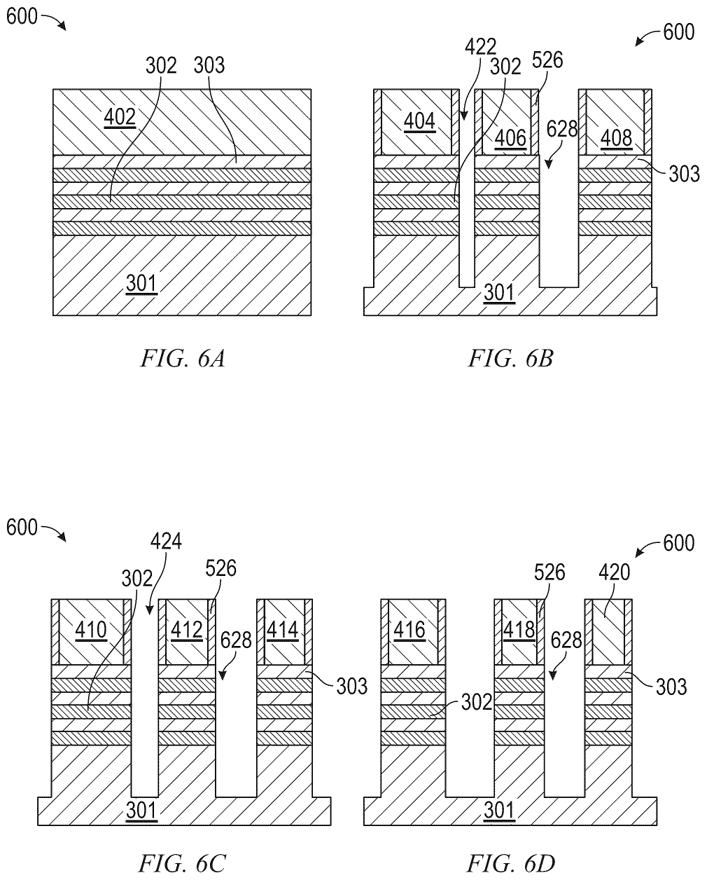

At 208, etch the nanosheet stack 300 to form a structure 600, as shown in FIGS. 6A-6D. The dielectric spacers 526 limit the etch to form trenches 628 that are relatively narrow compared to what could be achieved by conventional lithography and etching alone.

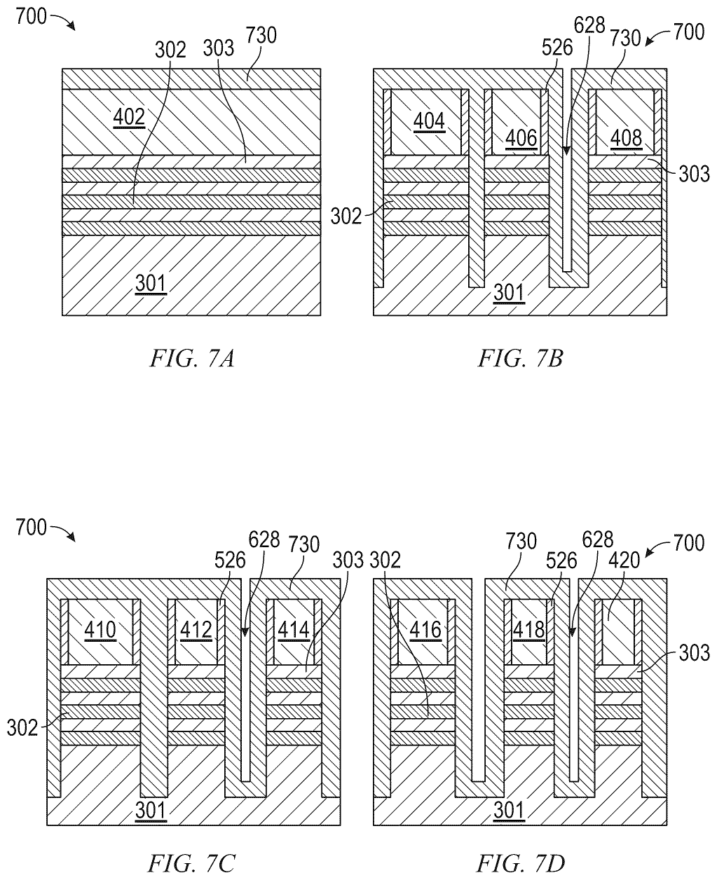

At 210, deposit a dielectric liner 730, as shown in FIG. 7A-7D, to form a structure 700. The dielectric liner 730 conforms to previous surfaces. Where the trenches 628 in FIGS. 6A-6D are narrower than twice a thickness of the dielectric liner, e.g., less than 35 nm wide, the dielectric liner completely or nearly completely fills the trenches. Where the trenches 628 in FIGS. 6A-6D are wider than twice the thickness of the dielectric liner, inward vertical surfaces of the dielectric liner 730 remain exposed to later etching. This sets up another aspect of the invention.

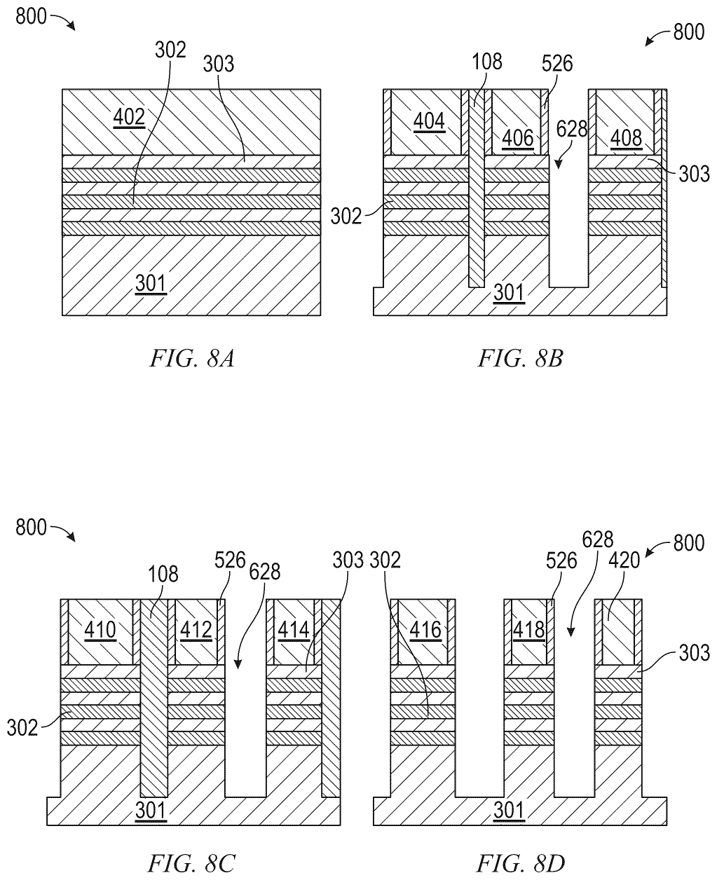

At 212, etch back the dielectric liner 730 to form a structure 800 that has forksheet dielectric pillars 108, as shown in FIGS. 1A-1E and 8A-8D (wherein the pillars are seen in FIGS. 8B and 8C). Where the dielectric liner 730 in FIGS. 7A-7D completely fills a trench 628, it is “pinched off”; that is, the etch does not remove the deep part of the dielectric liner from that trench. Where the inward vertical surfaces of the dielectric liner 730 are exposed, i.e., in a trench that is wider than twice the thickness of the dielectric liner in FIGS. 7A-7D, then the etch removes the dielectric liner from the trench. A result of this difference is that in a further step, gate metal can be deposited into some of the trenches from which the dielectric liner has been removed, whereas the dielectric liner forms the pillars 108 in the trenches from which it has not been removed. This is another aspect of the invention.

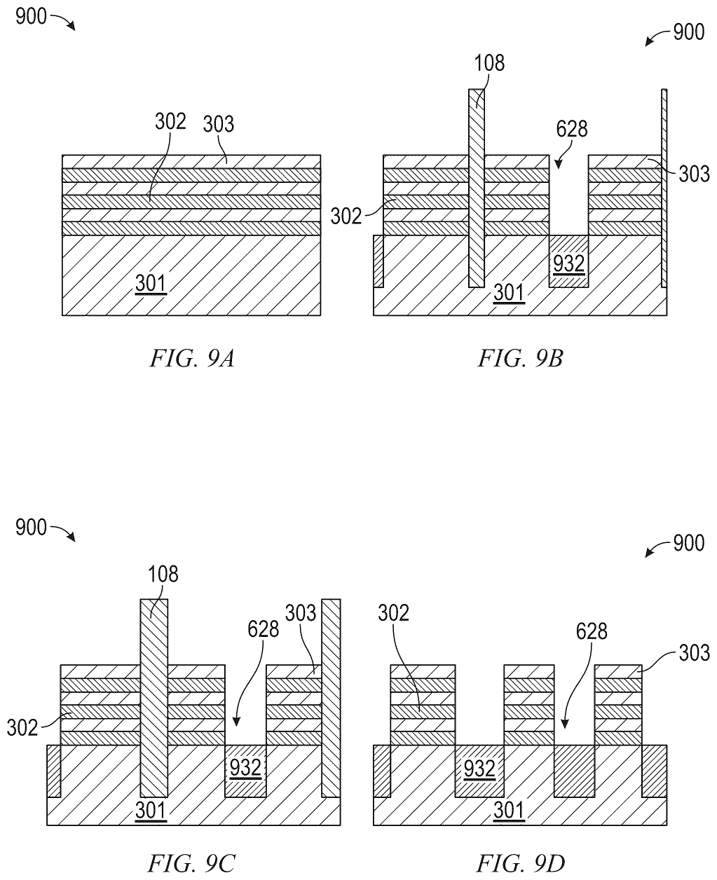

Steps 214 and 216, which produce the structure 900 that is shown in FIGS. 9A-9D, will now be discussed. At 214, form shallow trench isolation (STI) 932 at the bottoms of the trenches from which the dielectric liner 730 was removed in step 212. STI may be formed of any currently-known or later developed substance for providing electrical insulation, and as examples may include: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. STI may be formed to a height above the height of substrate and reveal at least some portion of precursor insulator layer. STI may be formed by chemical vapor deposition (CVD) or atomic layer deposition (ALD) dielectric deposition followed by chemical mechanical planarization (CMP) and recessing.

Also, at 216, remove the hardmask caps and the spacers.

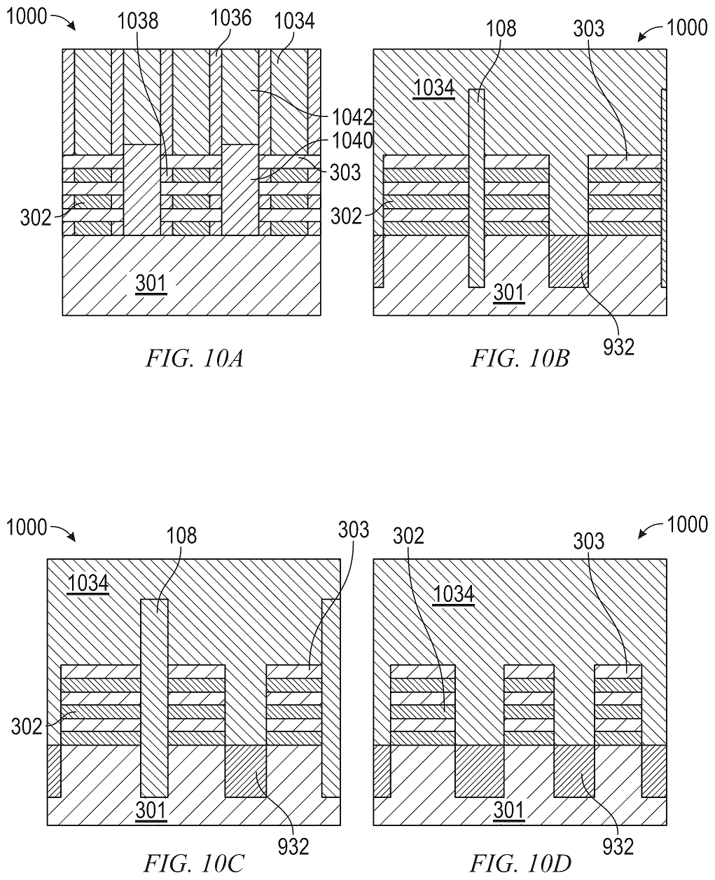

At 218, pattern dummy gates 1034, form spacers 1036 and inner spacers 1038, form source/drain structures 1040, fill interlayer dielectric 1042, and complete chemical-mechanical planarization to produce the structure 1000 that is shown in FIGS. 10A-10D. In one or more embodiments, the source/drain structures may be epitaxially grown from the substrate 301. In one or more embodiments, the source/drain structures may be epitaxially grown from the semiconductor nanosheets 303.

At 220, remove dummy gate and sacrificial SiGe, form replacement gate 106, and form the shared gate connectors 122 to provide the structure 100 that is shown in FIGS. 1A-1E. In one or more embodiments, the gate stacks 106 are high-k metal gate (HKMG) stacks. HKMGs comprise a high-k dielectric layer in combination with a metal gate feature. The term “high-K” has a definite meaning to the skilled artisan in the context of high-K metal gate (HKMG) stacks, and is not a mere relative term. The high-k dielectric layer may comprise, as just a few non-limiting examples, hafnium silicon oxide, zirconium silicon oxide, hafnium oxide, or zirconium oxide. The metal gate feature may comprise, again, as just a few non-limiting examples, a work-function-tunable material such as titanium nitride, titanium aluminum nitride, titanium silicon nitride, tantalum nitride, tantalum aluminum nitride, or tantalum silicon nitride. The components of the HKMGs may, in one or more embodiments, be deposited by atomic layer deposition (ALD), CVD, or some combination of those two processes.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

A number of different precursors may be used for the epitaxial deposition of the in situ doped semiconductor material. In some embodiments, the gas source for the deposition of an epitaxially formed in situ doped semiconductor material may include silicon (Si) deposited from silane, di silane, trisilane, tetrasilane, hexachlorodisilane, tetrachlorosilane, dichlorosilane, trichlorosilane, disilane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, which forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (ME), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Various structures that are described herein, e.g., source/drain structures, may be epitaxially grown. “Epitaxy” or “epitaxial growth,” as used herein, refers to a process by which a layer of single-crystal or large-grain polycrystalline material is formed on an existing material with similar crystalline properties. One feature of epitaxy is that this process causes the crystallographic structure of the existing substrate or seed layer (including any defects therein) to be reproduced in the epitaxially grown material. Epitaxial growth can include heteroepitaxy (i.e., growing a material with a different composition from its underlying layer) or homoepitaxy (i.e., growing a material which includes the same composition as its underlying layer). Heteroepitaxy can introduce strain in the epitaxially grown material, as its crystal structure may be distorted to match that of the underlying layer. In certain applications, such strain may be desirable. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

Gate stacks in both nFET and pFET structures (in embodiments having both types of regions) include work function material (WFM) layers. Non-limiting examples of suitable work function (gate) metals include p-type work function materials and n-type work function materials. P-type work function materials include compositions such as ruthenium, palladium, platinum, cobalt, nickel, and conductive metal nitride like TiN, WN, or any combination thereof. N-type work function materials include compositions such as hafnium, zirconium, titanium, tantalum, aluminum, metal carbides (e.g., hafnium carbide, zirconium carbide, titanium carbide, and aluminum carbide), aluminides, or any combination thereof.

The work function material(s) may be deposited by a suitable deposition process, for example, ALD, CVD, PECVD, PVD, plating, and thermal or e-beam evaporation. Pinch-off of work function material between semiconductor fins is essentially avoided during deposition. The WFM layer is removed from one of the nFET and pFET regions in structures including both types of regions while the other region is protected. An SC1 etch, an SC2 etch or other suitable etch processes can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of nFET devices is sensitive to the thickness of work function materials such as titanium nitride (TiN).

Given the discussion thus far, it will be appreciated that, in general terms, an exemplary semiconductor structure, according to an aspect of the invention, includes a common substrate; a forksheet complementary metal oxide semiconductor (CMOS) device that is located (e.g., formed) on the common substrate; and a gate-all-around (GAA) nanosheet CMOS device that is located (e.g., formed) on the common substrate and is adjacent to the forksheet device. In one or more embodiments, the forksheet CMOS device includes an nFET (n-doped Field Effect Transistor) and a pFET (p-doped Field Effect Transistor) and a dielectric pillar separating the nFET from the pFET; the dielectric pillar is not more than 35 nm thick. In one or more embodiments, the dielectric pillar is not less than 8 nm thick.

In one or more embodiments, the exemplary semiconductor structure also includes additional CMOS devices; a space between active regions of adjacent pFETs or nFETs of adjacent CMOS devices is greater than a thickness of a thickest dielectric pillar in the CMOS devices. In one or more embodiments, for a given CMOS device with more than 35 nm between its nFET and its pFET, both the nFET and the pFET of the given CMOS device are gate-all-around transistors with a shared gate stack. In one or more embodiments, for a given CMOS device with less than 35 nm between its nFET and its pFET, both the nFET and the pFET of the given CMOS device are tri-gate devices that include channels and a dielectric pillar separating the channels; proximal edges of the nFET and the pFET channels are attached to the dielectric pillar.

According to another aspect, an exemplary method includes etching a hardmask on a nanosheet stack to simultaneously form a plurality of hardmask caps over a plurality of pFET (p-doped Field Effect Transistor) and nFET (n-doped Field Effect Transistor) precursor regions, wherein spaces of varying widths separate the hardmask caps at different locations of the nanosheet stack; depositing spacers on the hardmask and reactive ion etching the spacers to form gaps that correspond to the spaces that were separating the hardmask caps; forming trenches of varying widths by etching the nanosheet stack through the gaps; depositing a sacrificial liner with a liner thickness on the hardmask caps and into the trenches; isotropically etching back the sacrificial liner so that portions of the sacrificial liner are removed from trenches that are wider than twice the liner thickness, while other portions of the sacrificial liner remain in pinch-off trenches that are narrower than twice the liner thickness; and completing a plurality of complementary metal-oxide-silicon transistors that include p-doped and n-doped source/drain structures in respective ones of the pFET and the nFET precursor regions, with dielectric material filling the trenches between the pFET and nFET precursor regions.

In one or more embodiments, the forming of the trenches of varying widths includes forming, between the nFET precursors regions and the pFET precursor regions, trenches that are not more than 35 nm wide. In one or more embodiments, the forming of the trenches of varying widths incudes forming, between pairs of adjacent nFET precursor regions and between pairs of adjacent pFET precursor regions, trenches that are at least 35 nm wide.

In one or more embodiments, depositing the sacrificial liner includes depositing the liner to a thickness that is not less than 15 nm.

In one or more embodiments, reactive ion etching the spacers includes forming at least one gap that is less than 8 nm wide.

According to another aspect, an exemplary semiconductor structure includes a common substrate; a first forksheet complementary metal oxide semiconductor (CMOS) device that is located (e.g., formed) on the common substrate and that has an nFET (n-doped Field Effect Transistor) and a pFET (p-doped Field Effect Transistor) and has a first β (effective width ratio) between the nFET and the pFET; and a second forksheet device that is adjacent to the first forksheet device on the common substrate and that has a second β between a second nFET and a second pFET. The second β is different than the first β by at least 5 percent.

In one or more embodiments, the first forksheet device includes a first dielectric pillar and the second forksheet device includes a second dielectric pillar, wherein the first and second pillars are of different thicknesses. In one or more embodiments, each forksheet device includes an nFET structure and a pFET structure and a dielectric pillar that separates the nFET structure from the pFET structure; each of the dielectric pillars is not more than 35 nm thick.

In one or more embodiments, the exemplary semiconductor structure also includes an intervening dielectric that separates the first and second forksheet devices; the intervening dielectric is more than 35 nm thick.

In one or more embodiments, each of the dielectric pillars is not less than 8 nm thick.

In one or more embodiments, the exemplary semiconductor structure also includes a shared gate connector that bridges the dielectric pillar in the first forksheet device.

In one or more embodiments, the exemplary semiconductor structure also includes a gate-all-around nanosheet CMOS device that is located (e.g., formed) on the common substrate and is adjacent to one of the forksheet devices.

In one or more embodiments, for a given one of the first and second forksheet devices, a distance between its nFET and its pFET is less than 35 nm and for the gate-all-around device a distance between its nFET and its pFET is more than 35 nm.

In one or more embodiments, the exemplary semiconductor structure also includes a dielectric isolator at least 35 nm thick that separates the gate-all-around device from an adjacent one of the forksheet devices.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a common substrate;
a forksheet complementary metal oxide semiconductor (CMOS) device that is located on the common substrate; and
a gate-all-around (GAA) nanosheet CMOS device that is located on the common substrate and is adjacent to the forksheet device.

2. The structure of claim 1, wherein the forksheet CMOS device includes an nFET (n-doped Field Effect Transistor) and a pFET (p-doped Field Effect Transistor) and a dielectric pillar separating the nFET from the pFET, wherein the dielectric pillar is not more than 35 nm thick.

3. The structure of claim 2, wherein the dielectric pillar is not less than 8 nm thick.

4. The structure of claim 2, further comprising additional CMOS devices, wherein a space between active regions of adjacent pFETs or nFETs of adjacent CMOS devices is greater than a thickness of a thickest dielectric pillar in the CMOS devices.

5. The structure of claim 4, wherein, for a given CMOS device with more than 35 nm between its nFET and its pFET, both the nFET and the pFET of the given CMOS device are gate-all-around transistors with a shared gate stack.

6. The structure of claim 4, wherein for a given CMOS device with less than 35 nm between its nFET and its pFET, both the nFET and the pFET of the given CMOS device are tri-gate devices that include channels and a dielectric pillar separating the channels, wherein proximal edges of the nFET and the pFET channels are attached to the dielectric pillar.

7. A method comprising:
etching a hardmask on a nanosheet stack to simultaneously form a plurality of hardmask caps over a plurality of pFET (p-doped Field Effect Transistor) and nFET (n-doped Field Effect Transistor) precursor regions, wherein spaces of varying widths separate the hardmask caps at different locations of the nanosheet stack;
depositing spacers on the hardmask and reactive ion etching the spacers to form gaps that correspond to the spaces that were separating the hardmask caps;
forming trenches of varying widths by etching the nanosheet stack through the gaps;
depositing a sacrificial liner with a liner thickness on the hardmask caps and into the trenches;
isotropically etching back the sacrificial liner so that portions of the sacrificial liner are removed from trenches that are wider than twice the liner thickness, while other portions of the sacrificial liner remain in pinch-off trenches that are narrower than twice the liner thickness; and
completing a plurality of complementary metal-oxide-silicon transistors that include p-doped and n-doped source/drain structures in respective ones of the pFET and the nFET precursor regions, wherein dielectric material fills the trenches between the pFET and nFET precursor regions.

8. The method of claim 7, wherein, in the forming of the trenches of varying widths, the trenches include, between the nFET precursors regions and the pFET precursor regions, a subset of the trenches that are not more than 35 nm wide.

9. The method of claim 7, wherein, in the forming of the trenches of varying widths, the trenches include, between pairs of adjacent nFET precursor regions and between pairs of adjacent pFET precursor regions, a subset of the trenches that are at least 35 nm wide.

10. The method of claim 9, wherein depositing the sacrificial liner comprises depositing the liner to a thickness that is not less than 15 nm.

11. The method of claim 7, wherein reactive ion etching the spacers comprises forming at least one gap that is less than 8 nm wide.

12. A semiconductor structure comprising:
a common substrate;
a first forksheet complementary metal oxide semiconductor (CMOS) device that is located on the common substrate and that has an nFET (n-doped Field Effect Transistor) and a pFET (p-doped Field Effect Transistor) and has a first β (effective width ratio) between the nFET and the pFET; and
a second forksheet device that is adjacent to the first forksheet device on the common substrate and that has a second β between a second nFET and a second pFET, wherein the second β is different than the first β by at least 5 percent.

13. The structure of claim 12, wherein the first forksheet device includes a first dielectric pillar and the second forksheet device includes a second dielectric pillar, wherein the first and second pillars are of different thicknesses.

14. The structure of claim 13, wherein each of the dielectric pillars is not less than 8 nm thick.

15. The structure of claim 13, further comprising a shared gate connector that bridges the dielectric pillar in the first forksheet device.

16. The structure of claim 12, wherein each forksheet device includes an nFET structure and a pFET structure and a dielectric pillar that separates the nFET structure from the pFET structure, wherein each of the dielectric pillars is not more than 35 nm thick.

17. The structure of claim 12, further comprising an intervening dielectric that separates the first and second forksheet devices, wherein the intervening dielectric is more than 35 nm thick.

18. The structure of claim 12, further comprising:
a gate-all-around nanosheet complementary metal oxide semiconductor (CMOS) device that is located (e.g., formed) on the common substrate and is adjacent to one of the forksheet devices.

19. The structure of claim 18, wherein for a given one of the first and second forksheet devices, a distance between its nFET and its pFET is less than 35 nm and for the gate-all-around device a distance between its nFET and its pFET is more than 35 nm.

20. The structure of claim 19, further comprising a dielectric isolator at least 35 nm thick that separates the gate-all-around device from an adjacent one of the forksheet devices.
